(19) United States
(12) Patent Application Publication
(10) Pub. No.: US 2016/0174381 A1
(43) Pub. Date: Jun. 16, 2016

(54) EMBEDDED PRINTED CIRCUIT BOARD AND METHOD OF MANUFACTURING THE SAME

(71) Applicant: Samsung Electro-Mechanics Co., Ltd., Suwon-si (KR)

(72) Inventors: Chang-Bo LEE, Suwon-si (KR); Do-Wan KIM, Changwon-si (KR)

(73) Assignee: Samsung Electro-Mechanics Co., Ltd., Suwon-si (KR)

(21) Appl. No.: 14/948,845

(22) Filed: Nov. 23, 2015

(30) Foreign Application Priority Data
Dec. 10, 2014 (KR) 10-2014-0177745

(51) Int. Cl. H05K 1/18; H05K 3/10; H05K 3/46; H05K 3/40; H05K 1/11; H05K 1/02

(52) U.S. Cl. CPC H05K 1/183; H05K 1/115; H05K 1/0298; H05K 3/4697; H05K 3/4038; H05K 3/10; H05K 3/4611; H05K 2203/06

(57) ABSTRACT

A printed circuit board in which an electronic component is embedded and a method of manufacturing the same are provided. The printed circuit board includes a first insulation layer with a first via and a cavity formed therein, the first insulation layer comprising a photosensitive material, an electronic component having at least a portion thereof positioned into the cavity, and a second insulation layer having a second via that is connected with the first via, the second insulation layer being laminated on the first insulation layer so as to embed the electronic component.

### CROSS-REFERENCE TO RELATED APPLICATIONS

This application claims the benefit under 35 USC 119(a) of Korean Patent Application No. 10-2014-0177745, filed on Dec. 10, 2014, in the Korean Intellectual Property Office, the entire disclosure of which is incorporated herein for all purposes.

### BACKGROUND

1. Field

The following description relates to a printed circuit board with an electronic component embedded therein and a method of manufacturing the same.

2. Description of Related Art

With the recent decrease in the size of electronic products, there exists a demand for producing smaller and thinner printed circuit boards with multifuntionality for mounting semiconductor elements in electronic devices. To meet these demands, various types of PCBs and PCB manufacturing methods have been developed.

In one example, coreless printed circuit boards are introduced in order to cope with these demands. Coreless printed circuit boards are printed circuit boards having no core included therein and have functional abilities that is comparable to printed circuit boards having a core substrate included therein; by not having a core substrate, the coreless printed circuit boards may be made thinner than the printed circuit boards in which a core substrate is included therein. Moreover, it is easier to implement finer circuits due to the properties of the coreless method.

In another example, electronic component-embedded printed circuit boards having an active component or a passive component embedded therein are introduced in order to cope with these demands. However, these electronic component-embedded printed circuit boards need to function as connectors that connect electronic components with the printed circuit boards while the printed circuit boards need to function as power supply capacitors or inductors.

In recent years, in order to implement the coreless printed circuit boards and the electronic component-embedded printed circuit boards described above and manufacturing methods thereof, a new PCB structure combining an embedded trace substrate (ETS) and an embedded passive substrate (EPS) and a manufacturing method thereof are introduced and regarded as an alternative solution that has both advantages of the coreless printed circuit boards and the electronic component embedded-printed circuit boards.

In general, a conventional ETS+EPS method that forms a PCB that combines embedded trace substrate and embedded passive substrate involves a process in which an adhesive is coated on a substrate having patterns formed thereon, an electronic component is placed on the adhesive, preprag having a cavity formed therein is prepared, and then the preprag is laminated on the substrate on which the electronic component is placed.

However, this method still imposes the following difficulties. First, it may be difficult to arrange a cavity with an electronic component being inserted in the cavity, compared to a general cavity-component arrangement in other methods, when the preprag having a size, which is almost the same as the electronic component, of a cavity formed therein is laminated on the substrate on which the electronic component is placed. Secondly, because a plated through hole (PTH) is formed by a drilling process and then plated with a blind via hole (BVH) for electrical connection between an upper surface and a lower surface of a substrate, there may be a void occurred inside the PTH due to a difference in depth between the PTH and the BVH, causing serious problems. Thirdly, there may be a void occurred in the final product due to the density of copper patterns and the fluidity of an adhesive material when the adhesive material is coated, making the warpage problem more serious and significantly deteriorating the product reliability. Fourthly, it may be difficult to prevent the warpage due to the limited control parameters while it is difficult to employ various types of materials for inner layers due to the uncertainty of fluidity of resin, for example, preprag, when the preprag is laminated. Additionally, a separated copper pattern may not be formed on a same layer in a horizontal direction of the electronic component through the conventional ETS+EPS method.

An example of a coreless printed circuit board is disclosed in Korea Patent No. 10-1167787 B1.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board includes a first insulation layer with a first via and a cavity formed therein, the first insulation layer comprising a photosensitive material, an electronic component having at least a portion thereof positioned into the cavity, and a second insulation layer having a second via that is connected with the first via, the second insulation layer being laminated on the first insulation layer so as to embed the electronic component.

The electronic component may be fixed within the cavity by an adhesive.

The adhesive may be disposed between the first insulation layer and the second insulation layer.

The general aspect of the printed circuit board may further include a circuit pattern interposed between the first insulation layer and the second insulation layer and embedded in a lower side of the second insulation layer.

The general aspect of the printed circuit board may further include a circuit pattern embedded in a lower side of the first insulation layer.

The general aspect of the printed circuit board may further include a circuit pattern that protrudes from the lower side of the first insulation layer.

The general aspect of the printed circuit board may further include a circuit pattern disposed in an upper side of the second insulation layer.

The general aspect of the printed circuit board may further include a third via connected with the electronic component and disposed on the second insulation layer, and a fourth via connected with the electronic component and disposed on the first insulation layer.

The first via and the second via may be tapered in a same direction, and the third via and the forth via are tapered in an opposite direction from each other.

The cavity may be spaced apart by a predetermined distance from a circuit pattern embedded in a lower side of the first insulation layer.

The first insulation layer may include photosensitive epoxy, and the second insulation layer may include at least one selected from the group consisting of photosensitive epoxy, prepreg and Ajinomoto build-up film (ABF).

In another general aspect, a method of manufacturing an embedded printed circuit board involves forming a cavity in a first insulation layer comprising a photosensitive material, forming a first via that penetrates the first insulation layer, positioning at least a portion of an electronic component into the cavity, laminating a second insulation layer on the first insulation layer to embed the electronic component, and forming a second via that penetrates the second insulation layer, the second via connected to the first via.

The cavity may be formed by exposing and developing processes.

The general aspect of the method may further involve, prior to the forming of the cavity, forming a circuit pattern embedded in a lower side of the first insulation layer, wherein the forming of the first via further involves forming a circuit pattern on an upper side of the first insulation layer.

The general aspect of the method may further involve, after the forming of the second via, forming a circuit pattern that protrudes from the lower side of the first insulation layer and forming a circuit pattern on an upper side of the second insulation layer.

The forming of the second via may further involve forming a third via, connected to the electronic component, on the second insulation layer and forming a fourth via, connected to the electronic component, on the first insulation layer.

The first via and the second via may be tapered in a same direction, and the third via and the fourth via may be tapered in an opposite direction from each other.

The first insulation layer may include photosensitive epoxy, and the second insulation layer includes any one of photosensitive epoxy, prepreg and Ajinomoto build-up film (ABF).

In another general aspect, a method of manufacturing an embedded printed circuit board involves laminating a first insulation layer on a carrier substrate, the first insulation layer comprising a photosensitive material, and the carrier substrate having a first circuit pattern formed on one surface or both surfaces thereof, forming a cavity and a first via in the first insulating layer and forming a second circuit pattern on the first insulation layer, positioning at least a portion of an electronic component into the cavity, laminating a second insulation layer on the first insulation layer so as to cover the electronic component, separating a laminate comprising the first insulation layer and the second insulation layer from the carrier substrate, and forming a second via and a third via in the second insulation layer, the second via being connected to the first via, and the third via being connected to the electronic component.

Other features and aspects will be apparent from the following detailed description, the drawings, and the claims.

### BRIEF DESCRIPTION OF DRAWINGS

FIGS. 1 to 15 are cross-sectional views illustrating an example of a method of manufacturing an embedded printed circuit board.

FIGS. 16 to 18 are cross-sectional views illustrating another example of a method of manufacturing an embedded printed circuit board.

FIG. 19 is a cross-sectional view illustrating an example of an embedded printed circuit board.

FIG. 20 is a cross-sectional view illustrating another example of an embedded printed circuit board.

FIG. 21 is a cross-sectional view illustrating another example of an embedded printed circuit board.

FIG. 22 is a cross-sectional view illustrating another example of an embedded printed circuit board.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

The terms used in the present specification are merely used to describe various examples, and are not intended to limit the present description. An expression used in the singular encompasses the expression of the plural, unless it has a clearly different meaning in the context. In the present specification, it is to be understood that the terms such as “including” or “having,” and the like, are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Terms such as “first”, “second”, “one surface (side)” and “the other surface (side)” can be used in merely distinguishing one element from other identical or corresponding elements, but the above elements shall not be restricted to the above terms.

When one element is described to be “coupled” to another element, it does not refer to a physical, direct contact between these elements only, but it shall also include the possibility of yet another element being interposed between these elements and each of these elements being in contact with said yet another element.

Unless otherwise defined, all terms used herein, including technical or scientific terms, have the same meanings as those generally understood by those with ordinary knowledge in the field of art to which the present description belongs. Such terms as those defined in a generally used dictionary are to be interpreted to have the meanings equal to the contextual meanings in the relevant field of art, and are not to be interpreted to have ideal or excessively formal meanings unless clearly defined in the present application.

Certain embodiments of the present description will be described below in detail with reference to the accompanying drawings. Those components that are the same or are in correspondence are rendered the same reference numeral regardless of the figure number, and redundant descriptions are omitted. Before describing certain embodiments of the present description, a general principle and a system for obtaining 3-dimensional information using holography will be first described below.

Hereinafter, various examples of electronic component-embedded printed circuit boards and methods of manufacturing the same will be described in detail with reference to the accompanying drawings.

According to one example, a method of manufacturing a printed circuit board with an electronic component embedded therein eliminates the need to prepare preprag having a cavity formed therein, and no void occurs inside the PTH due to the difference in depth between the PTH and the BVH because the electronic component-embedded printed circuit board obtained according to the example does not have a PTH formed therein. Further, in an example of an electronic component-embedded printed circuit board obtained according to the present description, it is possible to prevent the occurrence of a void between a circuit pattern and an adhesive material when the adhesive material is coated. According to one example, it is also possible to form a circuit pattern embedded in a horizontal direction of the electronic component inserted in the cavity and to employ various types of materials for insulation layers. Thus, the electronic component-embedded printed circuit board exhibits improved electrical properties and warpage properties.

Method of Manufacturing an Embedded Printed Circuit Board

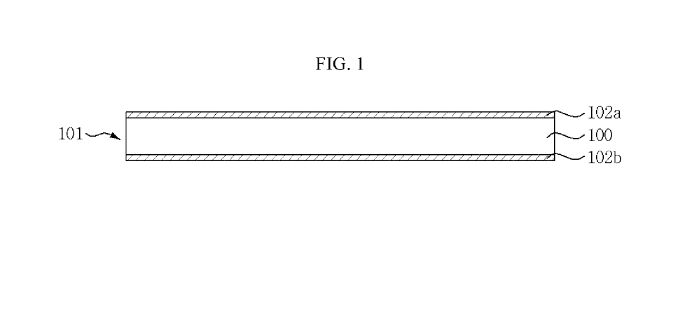

FIGS. 1 to 15 are cross-sectional views illustrating an example of a method of manufacturing an embedded printed circuit board.

Referring to FIG. 1, a carrier substrate 101 is prepared. The carrier substrate 101 includes an insulation layer 100 and plating seed layers 102a and 102b formed on either or both surfaces of the insulation layer 100. In this example, the plating seed layers 102a and 102b are provided such that they can be separated from the insulation layer 100 later in order to form the embedded printed circuit board.

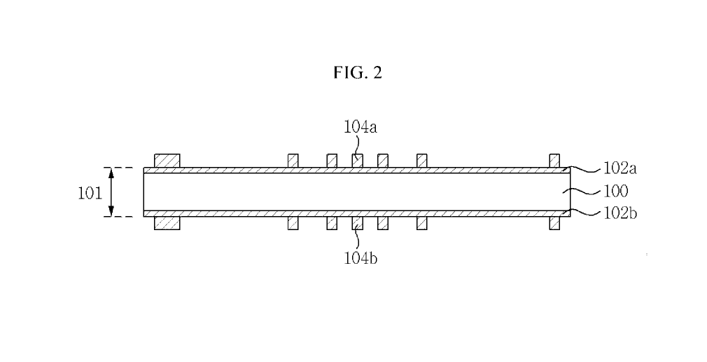

Next, referring to FIG. 2, first circuit patterns 104a and 104b are formed on the plating seed layers 102a and 102b through a circuit forming process. That is, the first circuit pattern 104a is formed above the plating seed layer 102a, and the first circuit pattern 104b is formed below the plating seed layer 102b.

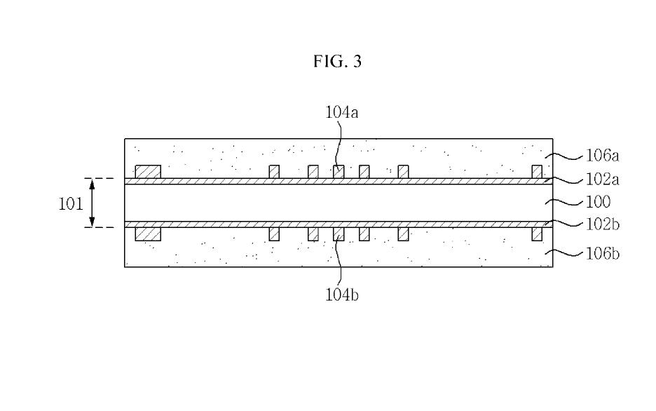

Next, referring to FIG. 3, first insulation layers 106a and 106b are laminated on either surface of the carrier substrate 101 having the first circuit patterns 104a and 104b formed thereon. In this example, the first insulation layers 106a and 106b are made of a photosensitive material such as, for example, photosensitive epoxy, having no glass fabric included therein.

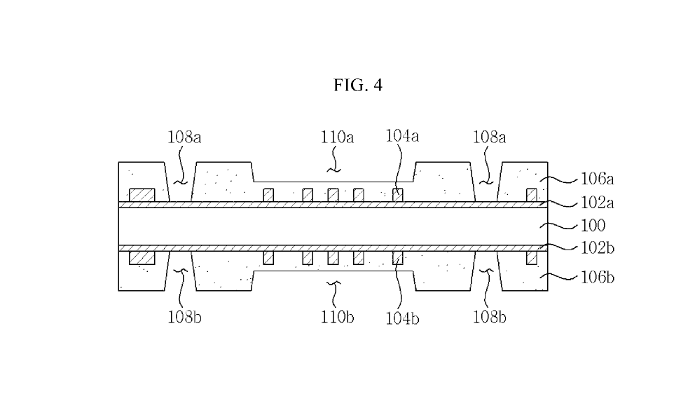

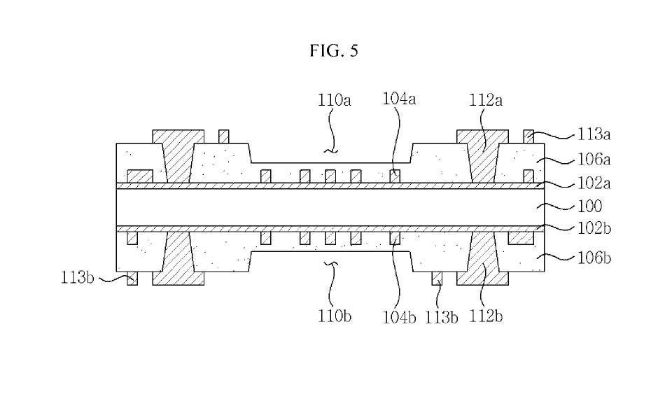

Next, referring to FIG. 4, cavities 110a and 110b are formed in the first insulation layers 106a and 106b through exposing and developing processes. That is, the cavity 110a is formed in the first insulation layer 106a, and the cavity 110b is formed in the first insulation layer 106b with reference to FIG. 4. The holes 108a and 108b for first vias 112a and 112b (refer to FIG. 5), which penetrate the first insulation layers 106a and 106b, are formed in the first insulation layers 106a and 106b through exposing and developing processes. That is, while the exposing and developing processes are performed, the hole 108a is formed in the first insulation layer 106a, and the hole 108b is formed in the first insulation layer 106b.

Referring to FIG. 4, the cavity 110a is formed to be spaced with a certain distance from the first circuit pattern 104a formed on the first insulation layer 106a, and the cavity 110b is formed to be spaced with a certain distance from the first circuit pattern 104b formed on the first insulation layer 106b.

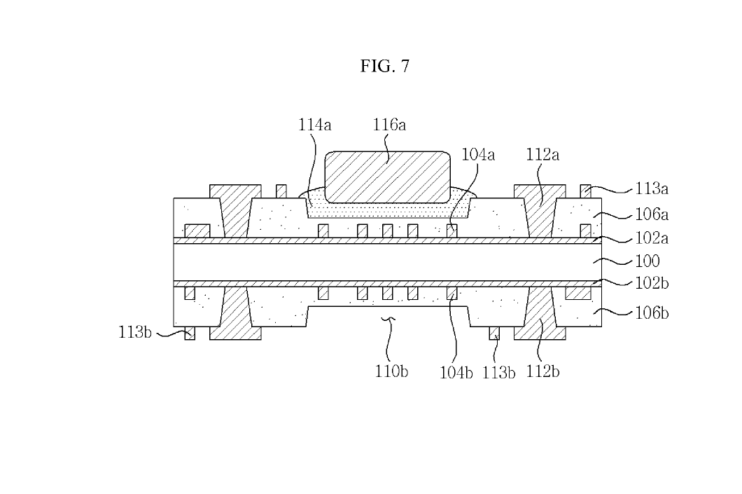

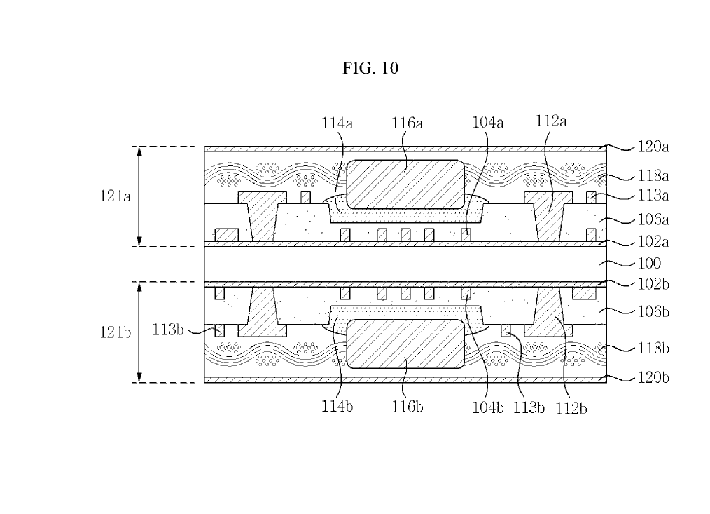

The cavities 110a and 110b are where at least some portions of electronic components (refer to 116a and 116b of FIGS. 7 to 9) are to be inserted in later. In this example, the cavities 110a and 110b are formed in the first insulation layers 106a and 106b, respectively, through exposing and developing processes. This method according to the present example does not require a process of preparing an insulation layer having a cavity corresponding to the size of an electronic component formed therein, compared to the conventional method of forming an embedded printed circuit board. Moreover, while laminating of second insulation layers (refer to 118a and 118b of FIG. 10) is performed in later, it is possible that the protruding electronic components 116a and 116b may be placed to have lower heights so that the electronic components 116a and 116b are prevented from being broken by external shocks.

While the first vias 108a and 108b, which penetrate the first insulation layers 106a and 106b, respectively, and the cavities 110a and 110b are formed in the first insulation layers 106a and 106b, each of which is made of photosensitive epoxy, a double-layer structure may be obtained, and this structure may be implemented by use of flat plug developing technology.

For the developing agent, a 1 percent by weight Na₂CO₃ solution is commonly used. However, in the event that a solution having a concentration of 2% by weight, 5 by weight, 10% by weight or the like is used as the developing agent by increasing the concentration of Na₂CO₃ contained in the solution, or if di-valent cation such as Mg²⁺, which is used for preventing the dissolution reaction, is used as the developing agent, it may slow down the developing speed, thereby making the space develop uniformly.

Accordingly, a structure that is obtained by multiple developing processes, as shown in FIG. 4, may be obtained by repeatedly exposing and developing the sensitive epoxy.

Next, referring to FIG. 5, the first vias 112a and 112b are formed in the first insulation layers 106a and 106b, respectively, through a circuit forming process. Likewise, second circuit patterns 113a and 113b are formed in the first insulation layers 106a and 106b, respectively, through a circuit forming process.

In a process which will be described later, because either of the second insulation layers 118a and 118b is laminated on either of the second circuit patterns 113a and 113b, the second circuit patterns 113a and 113b become circuit patterns that are embedded in a horizontal direction of the electronic components 116a and 116b.

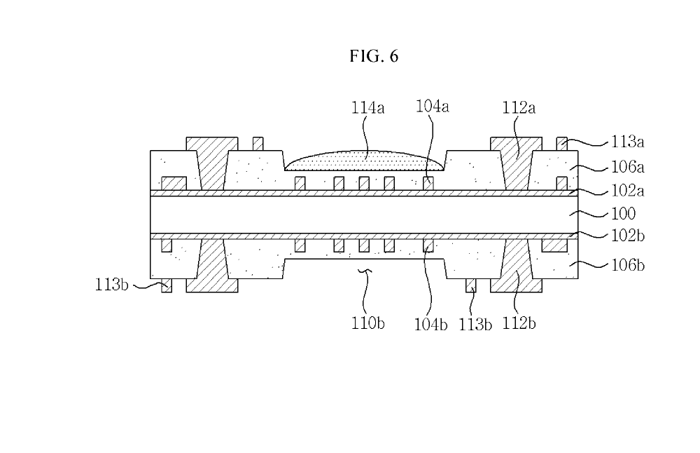

Next, referring to FIG. 6, an adhesive 114a is coated on the cavity 110a.

Next, referring to FIG. 7, a portion of the electronic component 116a is inserted in the cavity 114a, and then the electronic component 106a is fixed to the first insulation layer 106a by curing the adhesive 114a.

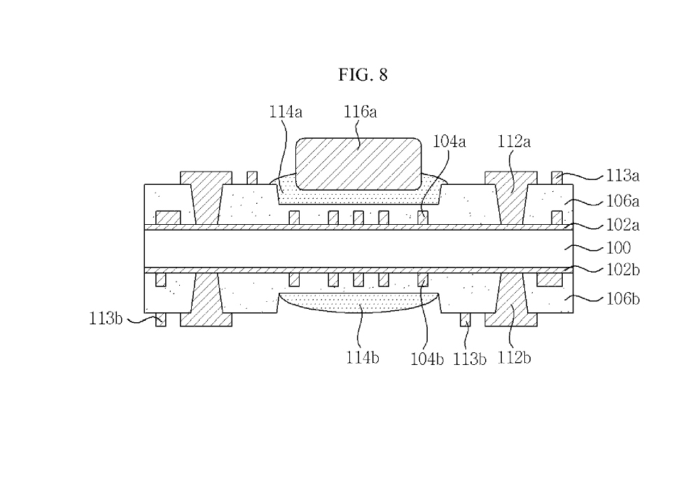

Next, referring to FIG. 8, an adhesive 114b is coated on the cavity 110b.

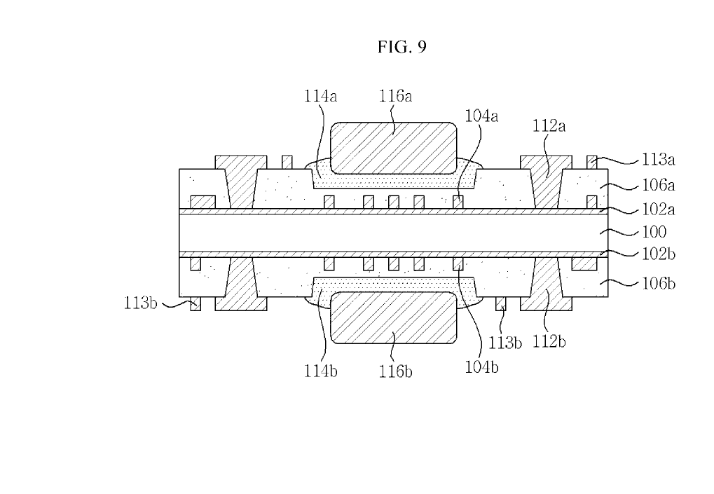

Next, referring to FIG. 9, a portion of the electronic component 116b is inserted in the cavity 114b, and then the electronic component 106b is fixed to the first insulation layer 106b by curing the adhesive 114b.

This example illustrates that the electronic components 116a and 116b are fixed to the first insulation layers 106a and 106b by use of the adhesives 114a and 114b while the adhesives 114a and 114b are coated on the cavities 110a and 110b. However, it shall be understood that the present description is not limited to this example, and the electronic components 116a and 116b may be fixed within the cavities 110a and 110b, respectively, without using an adhesive as long as the cavities 110a and 110b having the same sizes as the electronic components 116a and 116b are formed such that the electronic components 116a and 116b are inserted to the cavities 110a and 110b, respectively. That is, in the event that the cavities 110a and 110b are shaped to cope with the sizes and shapes of the electronic components 116a and 116b, the electronic components 116a and 116b may be fixed within the cavities 110a and 110b, respectively, without using an adhesive.

Next, referring to FIG. 10, the second insulation layers 118a and 118b, which have copper thin films 120a and 120b formed on one surface thereof, respectively, are laminated on the first insulation layers 106a and 106b, respectively, such that the electronic components 116a and 116b are embedded.

Although, in this example, the second insulation layers 118a and 118b having the copper thin films 120a and 120b formed on one surface thereof, respectively, are laminated on the first insulation layers 106a and 106b, respectively, the present description is not restricted to this example. In another example, second insulation layers 118a and 118b having no copper thin films formed on one surface thereof may be formed on the first insulation layers 106a and 106b.

The second insulation layers 118a and 118b may be made of photosensitive epoxy, prepreg and/or Ajinomoto build-up film (ABF).

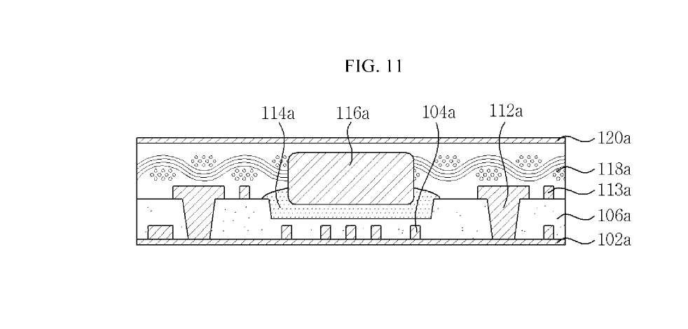

Next, referring to FIG. 11, a laminate 121a of the first insulation layer 106a and the second insulation layer 118a and a laminate 121b of the first insulation layer 106b and the second insulation layer 118b are separated from the insulation layer 100 of the carrier substrate 101.

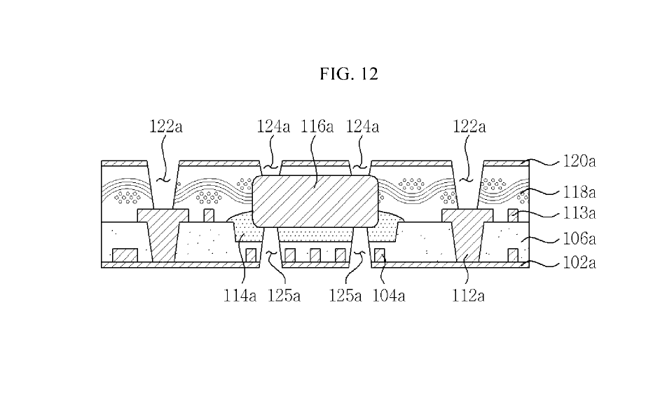

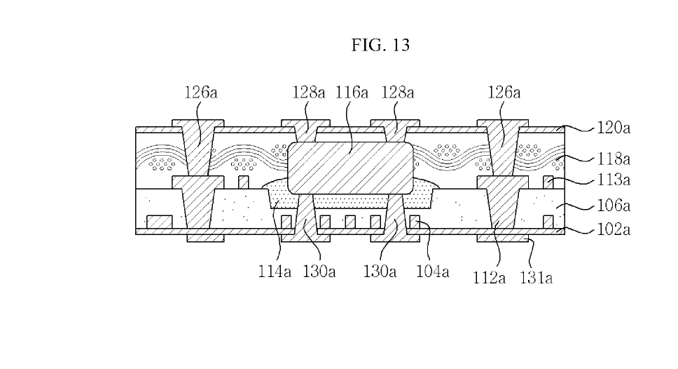

Next, referring to FIG. 12, a hole 122a, which is for a second via (126a of FIG. 13) penetrating the second insulation layer 118a and being connected to the first via 112a, and a hole 124a, which is for a third via (128a of FIG. 13) being connected to the electronic component 116a, are formed in the second insulation layer 118a. A hole 125a, which is for a forth via (130a of FIG. 13) being connected to the electronic component 116a, is formed in the first insulation layer 106a.

Next, referring to FIG. 13, a conductive material is filled into the hole 122a to form the second blind via 126a, the hole 124a to form the third blind via 128a and the hole 125a to form the fourth blind via 130. Then, a third circuit pattern (not shown) is patterned through circuit forming processes, so that the second via 126a, the third via 128a and a third circuit pattern 127 are formed in the second insulation layer 118a, and the forth via 130a and a fourth circuit pattern 131a are formed in the first insulation layer 106a.

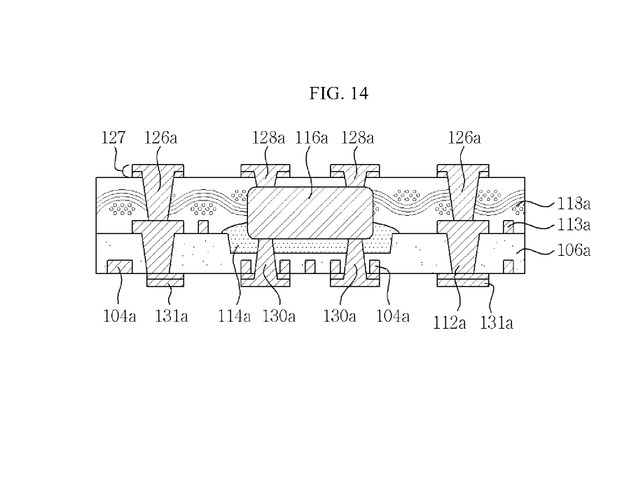

Next, referring to FIG. 14, the plating seed layer 102a and the copper thin film 120a are removed by etching.

In the embedded printed circuit board shown in FIG. 14, the first circuit pattern 104a is a circuit pattern that is embedded in a lower side of the first insulation layer 106a. The second circuit pattern 113a is a circuit pattern that is interposed between the first insulation layer 106a and the second insulation layer 118a and embedded in a lower side of the second insulation layer 118a. The third circuit pattern 127 is a circuit pattern that is formed on an upper side of the second insulation layer 118a. The fourth circuit pattern 131a is a circuit pattern that is protruded from the lower side of the first insulation layer 106a.

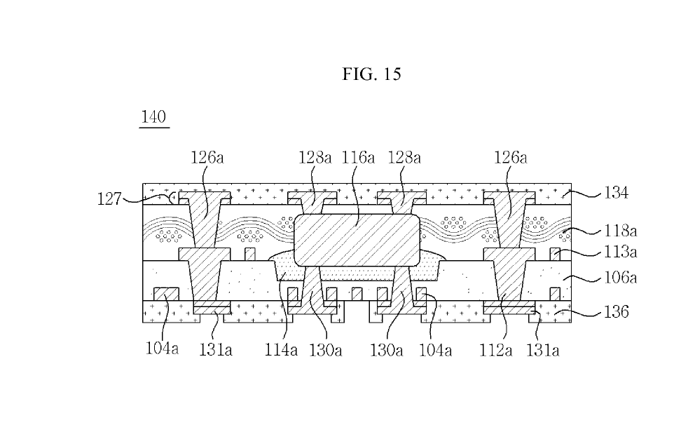

Next, referring to FIG. 15, an embedded printed circuit board 140 is formed by coating a solder resist 136 so as to cover the first insulation layer 106a, the fourth via 130a and the first circuit pattern 104a, and by coating a solder resist 134 so as to cover the second insulation layer 118a, the second via 126a, the third via 128a and the third circuit pattern (not shown).

In the example of the embedded printed circuit board 140 illustrated in FIG. 15, the first via 112a and the second via 126a are tapered in a same direction, and the third via 128a and the fourth via 130a are tapered in an opposite direction from each other. Here, the term “tapered” refers to the fact that the outer diameter becomes smaller toward the inside of the via.

That is, in the example of the embedded printed circuit board 140 illustrated in FIG. 15, both the first via 112a and the second via 126a are tapered in a same direction facing downward.

Moreover, since the third via 128a is tapered downward and the fourth via 130a is tapered upward, the third via 128a and the fourth via 130a are tapered in an opposite direction from each other.

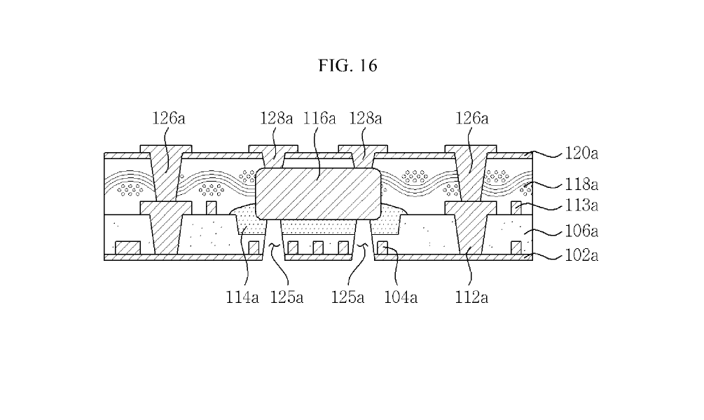

FIGS. 16 to 18 are cross-sectional views illustrating an example of a method of manufacturing an embedded printed circuit board.

FIGS. 16 to 18 are flow diagrams illustrating an example of a method of manufacturing an embedded printed circuit board, and the flow diagrams correspond to the flow steps of FIGS. 13 to 15, respectively, of the embodiment described earlier. Since various steps of the method in accordance with the earlier embodiment with respect to the step prior to FIG. 16 are the same as or substantially similar to the steps illustrated in FIGS. 1 to 12, repetitive explanations are omitted, and the differences are mainly described.

Referring to FIGS. 12 and 16, in the method of manufacturing an embedded printed circuit board in accordance with the illustrated example, the second via 126a, the third via 128a and the third circuit pattern (not shown) are formed on the second insulation layer 118a by filling a conductive material in the hole 122a for the second via 126a and in the hole 124a for the third via 128a and by patterning the third circuit pattern (not shown) through circuit forming processes.

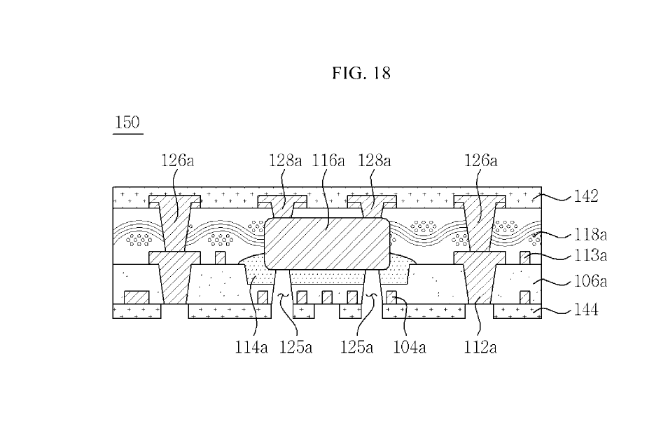

That is, in this example of a method of manufacturing an embedded printed circuit board, when patterning is performed on the outermost layer thereof, only a layer of one side is plated while a layer of the other side is not plated. Thus, a via being connected to the electronic component 116a is not formed in the layer of the other side where plating is omitted, i.e., the first insulation layer 106a. Accordingly, the first insulation layer 106a shown in FIG. 18 has the circuit pattern 104a and the first via 112a embedded therein but does not have the fourth via 130a shown in FIG. 15.

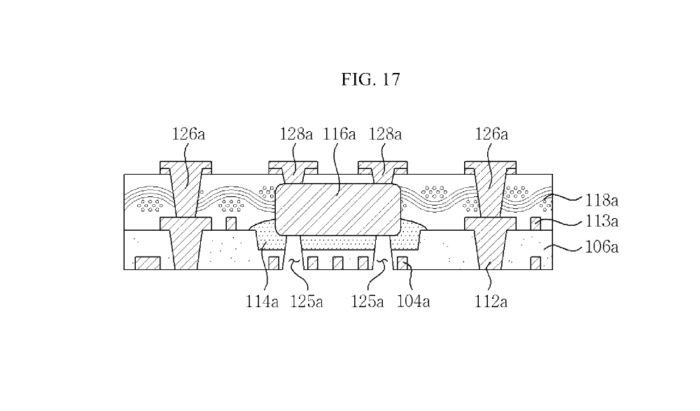

Next, referring to FIG. 17, the plating seed layer 102a and the copper thin film 120a are removed by use of etching.

Next, referring to FIG. 18, an embedded printed circuit board 150 is formed by coating a solder resist 144 so as to cover the first insulation layer 106a, the fourth via 130a and the first circuit pattern 104a, and by coating a solder resist 142 so as to cover the second insulation layer 118a, the second via 126a, the third via 128a and the third circuit pattern (not shown).

Embedded Printed Circuit Board

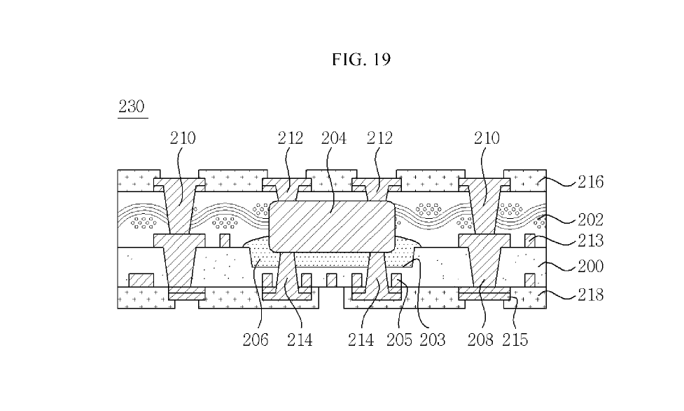

FIGS. 19 to 22 are cross-sectional views showing an example of an embedded printed circuit board in accordance with the present description.

Referring to FIG. 19, the embedded printed circuit board 230 includes: a first insulation layer 200 having a first via 208 and a cavity 203 formed therein and being made of a photosensitive material; an electronic component 204, a portion of the electronic component 204 being inserted in the cavity 203 and being fixed to the cavity 203 by use of an adhesive 206; and a second insulation layer 202 including a second via 210 being connected with the first via 208, the second insulation layer 202 being laminated on the first insulation layer 200 such that the electronic component 204 is embedded.

The adhesive 206 is surrounded by the first insulation layer 200 and the second insulation layer 202.

Moreover, in this example, the embedded printed circuit board 230 further includes: a first circuit pattern 205 being embedded in a lower side of the first insulation layer 200; a circuit pattern (not shown) being formed on an upper side of the second insulation layer 202; and a second circuit pattern 213 being interposed between the first insulation layer 200 and the second insulation layer 202 and being embedded in a lower side of the second insulation layer 202 in a horizontal direction of the electronic component 204.

Moreover, in this example, the embedded printed circuit board further includes: a third via 212 being connected with the electronic component 204 and being formed on the second insulation layer 202; a fourth via 214 being connected with the electronic component 204 and being formed on the first insulation layer 200; a circuit pattern 215; and solder resists 216 and 218.

In the embedded printed circuit board shown in FIG. 19, the first via 208 and the second via 210 are tapered in a same direction, and the third via 212 and the fourth via 214 are tapered in an opposite direction from each other. Here, the term “tapered” refers to the fact that the outer diameter becomes smaller toward the inside of the via.

That is, in the embedded printed circuit board 140 shown in FIG. 19, both the first via 208 and the second via 210 are tapered in a same direction facing downward.

Moreover, since the third via 212 is tapered downward and the fourth via 214 is tapered upward, the third via 212 and the fourth via 214 are tapered in an opposite direction from each other.

Moreover, the cavity 203 is formed to be spaced with a certain distance from the first circuit pattern 205, which is formed in a lower side of the first insulation layer 200.

Moreover, the first insulation layer 200 may be made of a photosensitive material such as photosensitive epoxy, and the second insulation layer 202 may be made of a material such as, for example, prepreg or Ajinomoto build-up film (ABF).

In the embedded printed circuit board 230 in accordance with the illustrated example, because the electronic component 204 is embedded in the insulation layers 200 and 202 by being covered by a pair of insulation layers including the first insulation layer 200 and the second insulation layer 202, and the circuit pattern 213 is embedded in a horizontal direction of the electronic component 204, the embedded printed circuit board may have multifunctionality while being made thinner in dimension.

Moreover, in the embedded printed circuit board 230 according to the present example, because the first circuit pattern 205 of the first insulation layer 200 and the circuit pattern (now shown) of the second insulation layer 202 are connected to each other through the first via 208, which penetrates the first insulation layer 200, and the second via 210, which penetrates the second insulation layer 202, there is no need to form one plated through hole (PTH) penetrating the first insulation layer 200 and the second insulation layer 202. As a result, according to this example of a method of manufacturing an embedded printed circuit board, it is possible to prevent the formation of a void that occurs inside a plated through hole due to a difference in depth when the plated through hole is formed.

Moreover, in the embedded printed circuit board 230 in accordance with the present description, since the adhesive 206 is coated on the cavity 203 formed in the first insulation layer 200 as the adhesive 206 is spaced from the circuit pattern 205 while the adhesive 206 is not directly coated on the circuit pattern 205, it is possible to prevent the occurrence of a void that is caused by the density of the circuit pattern 205 in a limited space and the fluidity of the adhesive 206 between the circuit pattern 205 and the adhesive 206.

Moreover, in the embedded printed circuit board 230 in accordance with the present example, since the insulation layers are made of various types of materials, it is also possible to improve the electrical property and warpage of the printed circuit board (PCB).

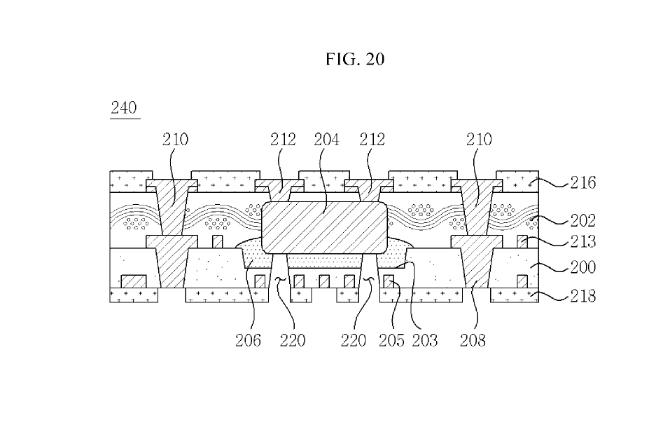

Another example of an embedded printed circuit board 240 illustrated in FIG. 20 has similar structures to that of the embedded printed circuit board 230 illustrated in FIG. 19. However, unlike the embedded printed circuit board 230 illustrated in FIG. 19, the first insulation layer 200 illustrated in FIG. 20 does not have a via being connected to the electronic component 204. Accordingly, the first insulation layer 200 shown in FIG. 20 has the first circuit pattern 205 and the first via 208 embedded therein but does not have the fourth via 214 shown in FIG. 19.

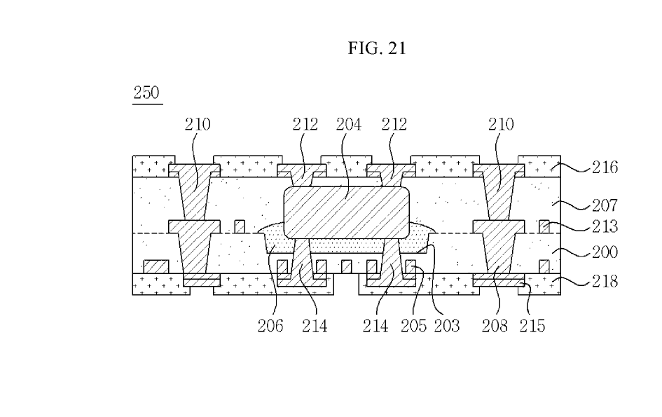

Another example of an embedded printed circuit board 250 shown in FIG. 21 has a structure similar to that of the embedded printed circuit board 230 illustrated in FIG. 19. However, unlike the embedded printed circuit board 230 of FIG. 19, the second insulation layer 207 may be made of the same material as that of the first insulation layer 200, which may be made of a photosensitive material such as photosensitive epoxy.

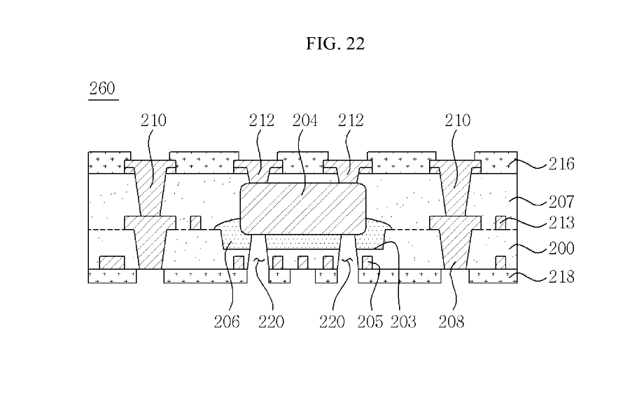

An embedded printed circuit board 260 according to yet another example is illustrated in FIG. 22. The embedded printed circuit board 260 according to FIG. 22 has a structure that is similar to that of the embedded printed circuit board 240 illustrated in FIG. 20. However, unlike the embedded printed circuit board 240 of FIG. 20, the second insulation layer 207 may be made of the same material as that of the first insulation layer 200, which is made of a photosensitive material such as photosensitive epoxy.

Described above are examples of electronic component-embedded printed circuit board and methods of manufacturing the same. According to an example of a method of manufacturing the embedded printed circuit board, there is no need to prepare preprag having a cavity formed therein, and no void occurs inside a PTH due to the difference in depth between a PTH and a BVH because the embedded printed circuit board does not include a PTH formed therein. Moreover, in the electronic component embedded printed circuit board in accordance with an example of the present description, it is possible to prevent a void between a circuit pattern and an adhesive material from occurring when the adhesive material is coated. It is also possible to form a circuit pattern embedded in a horizontal direction of the electronic component inserted in the cavity and to employ various types of materials for insulation layers. Thus, according to an example of an electronic component-embedded printed circuit board described above, the electrical properties and the warpage property of the printed circuit board may be improved.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
a first insulation layer with a first via and a cavity formed therein, the first insulation layer comprising a photosensitive material;
an electronic component having at least a portion thereof positioned into the cavity; and
a second insulation layer having a second via that is connected with the first via, the second insulation layer being laminated on the first insulation layer so as to embed the electronic component.

2. The printed circuit board of claim 1, wherein the electronic component is fixed within the cavity by an adhesive.

3. The printed circuit board of claim 2, wherein the adhesive is disposed between the first insulation layer and the second insulation layer.

4. The printed circuit board of claim 1, further comprising a circuit pattern interposed between the first insulation layer and the second insulation layer and embedded in a lower side of the second insulation layer.

5. The printed circuit board of claim 1, further comprising a circuit pattern embedded in a lower side of the first insulation layer.

6. The printed circuit board of claim 5, further comprising a circuit pattern that protrudes from the lower side of the first insulation layer.

7. The printed circuit board of claim 6, further comprising a circuit pattern disposed in an upper side of the second insulation layer.

8. The printed circuit board of claim 1, further comprising:
a third via connected with the electronic component and disposed on the second insulation layer; and
a fourth via connected with the electronic component and disposed on the first insulation layer.

9. The printed circuit board of claim 8, wherein the first via and the second via are tapered in a same direction, and the third via and the forth via are tapered in an opposite direction from each other.

10. The printed circuit board of claim 1, wherein the cavity is spaced apart by a predetermined distance from a circuit pattern embedded in a lower side of the first insulation layer.

11. The printed circuit board of claim 1, wherein the first insulation layer comprises photosensitive epoxy, and the second insulation layer comprises at least one selected from the group consisting of photosensitive epoxy, prepreg and Ajinomoto build-up film (ABF).

12. A method of manufacturing a printed circuit board, comprising:
forming a cavity in a first insulation layer comprising a photosensitive material;
forming a first via that penetrates the first insulation layer;
positioning at least a portion of an electronic component into the cavity;
laminating a second insulation layer on the first insulation layer to embed the electronic component; and
forming a second via that penetrates the second insulation layer, the second via connected to the first via.

13. The method of claim 12, wherein the cavity is formed by exposing and developing processes.

14. The method of claim 13, further comprising, prior to the forming of the cavity, forming a circuit pattern embedded in a lower side of the first insulation layer, wherein the forming of the first via further comprises forming a circuit pattern on an upper side of the first insulation layer.

15. The method of claim 14, further comprising, after the forming of the second via, forming a circuit pattern that protrudes from the lower side of the first insulation layer and forming a circuit pattern on an upper side of the second insulation layer.

16. The method of claim 12, wherein the forming of the second via further comprises forming a third via, connected to the electronic component, on the second insulation layer and forming a fourth via, connected to the electronic component, on the first insulation layer.

17. The method of claim 16, wherein the first via and the second via are tapered in a same direction, and the third via and the fourth via are tapered in an opposite direction from each other.

18. The method of claim 12, wherein the first insulation layer comprises photosensitive epoxy, and the second insulation layer comprises any one of photosensitive epoxy, prepreg and Ajinomoto build-up film (ABF).

19. A method of manufacturing a printed circuit board, comprising:
laminating a first insulation layer on a carrier substrate, the first insulation layer comprising a photosensitive material, and the carrier substrate having a first circuit pattern formed on one surface or both surfaces thereof;
forming a cavity and a first via in the first insulating layer and forming a second circuit pattern on the first insulation layer;
positioning at least a portion of an electronic component into the cavity;
laminating a second insulation layer on the first insulation layer so as to cover the electronic component;
separating a laminate comprising the first insulation layer and the second insulation layer from the carrier substrate; and
forming a second via and a third via in the second insulation layer, the second via being connected to the first via, and the third via being connected to the electronic component.
